(19) United States
(12) Patent Application Publication
(10) Pub. No.: US 2009/0086556 A1
(43) Pub. Date: Apr. 2, 2009

(54) Methods and apparatuses for operating memory

(76) Inventors: Sapumal Wijeratne, Portland, OR (US); Jeff Miller, Vancouver, WA (US)

Correspondence Address: SCHUBERT, OSTERRIEDER & NICKELSON, PLLC;c/o Intellevate, LLC, P.O. BOX 52050, MINNEAPOLIS, MN, 55402, US

(21) Appl. No.: 11/904,490

(22) Filed: Sep. 27, 2007

(51) Int. Cl. G11C 7/00

(52) U.S. Cl. 365/189.16

(57) ABSTRACT

A low voltage memory apparatus is disclosed. The memory apparatus can include a bit cell, a first pass gate coupled to the bit cell to receive a write signal, a second pass gate coupled to the bit cell to receive the write signal, and a bit cell isolator to isolate at least a portion of the bit cell from a power return during a write cycle. Isolating a cross coupled flip flop in the bit cell during a write cycle can provide faster write times, increased write reliability and can reduce the effects of device variations on bit cell operation, particularly for low voltage applications. Other embodiments are also disclosed.

### FIELD

Some embodiments disclosed herein relate to the field of computers and more particularly, to methods and apparatuses for configuring and operating a memory circuit.

### BACKGROUND

Manufacturers of computing systems continue to strive to make products that are more efficient. One way to make these systems more efficient is to reduce the size of devices such as transistors and correspondingly to the operating voltage of the system can be lowered. Many systems have processors that can operate at supply voltages under one volt, however memory systems that support processors often have a difficult time reliably operating under such low voltage conditions. Further, with the advent of multi-core processors, power conservation has become more important for battery powered computing systems such as laptop computers.

New low voltage manufacturing technologies that create devices on an integrated circuit that are smaller than 65-nm have created many additional technological challenges for designers of low voltage systems. One such challenge for smaller devices is related to higher intrinsic device variations. Accordingly, when manufacturing devices with such small dimensions it is hard to control the gate length (Le) of the devices and it is hard to control the threshold voltages (Vt) of these sub 65-nm devices. Circuit operations including circuit sensitivity to these parameters also becomes a significant challenge for circuit designers.

Generally, the minimum operating voltage (Vcc min) of a system is limited by a minimum voltage that is required to operate storage elements such as memory cells or bit cells that store data and instructions for the processor. It can be appreciated that the amount of high performance memory being provided for current processor designs is ever increasing. Processors chips that have this additional low voltage memory typically have a significant yield loss during acceptance testing and the burn in procedure. These lower yields have made manufacturers of processors reconsider if lower voltages are economically feasible and what operating voltage levels are economically practical. Hence, there has been a trend to design and operate current processors at higher voltages than previous technologies in an effort to provide an improved cost/performance trade off. It can be appreciated that manufacturers are investing alternate circuit topologies to the conventional memory structures that can operate at lower voltages and can be manufactured with higher yields.

### BRIEF DESCRIPTION OF THE DRAWINGS

FIG. 1 depicts a bit cell configuration;

FIG. 2 illustrates a more detailed view of a bit cell;

FIG. 3 depicts an isolator signal generator; and

FIG. 4 is a flow diagram of for controlling a memory system.

### DETAILED DESCRIPTION OF EMBODIMENTS

The following is a detailed description of some of embodiments depicted in the accompanying drawings. The embodiments are in such detail as to clearly communicate an invention. However, the amount of detail offered is not intended to limit the anticipated variations of embodiments; but on the contrary, the intention is to cover all modifications, equivalents, and alternatives falling within the spirit and scope of the some embodiments as defined by the appended claims. While specific embodiments will be described below with reference to particular circuit or logic configurations, those of skill in the art will realize that some embodiments disclosed may advantageously be implemented with other similar configurations.

In some embodiments, a low voltage memory apparatus is disclosed. The memory apparatus can include a bit cell, a first pass gate coupled to the bit cell to receive a write signal, a second pass gate coupled to the bit cell to receive the write signal, and a bit cell isolator to isolate at least a portion of the bit cell from a power return rail such as a ground rail during a write cycle. Isolating cross coupled inverters in the bit cell during a write cycle can provide improved low voltage performance, faster write times/cycles and can reduce the effects of device variations on bit cell or memory cell operation.

In other embodiments, a memory design is disclosed that can improve manufacturing yields for low voltage operation. An isolator in the form of a switch can be coupled between a node of a bit cell and ground or return to isolate the bit cell from ground during a write cycle. Isolating a portion of the bit cell during the write cycle can provide changes in internal voltages and currents of the bit cell and such isolation can assist in toggling the bit cell during a write cycle. The isolator can be driven by a signal that is the inverse of the write enable signal. In some embodiments, the bit cell configuration can be utilized by a processor as a cache or as a single write-port register file (RF). The disclosed system can provide improved switching performance when compared to traditional memory configurations.

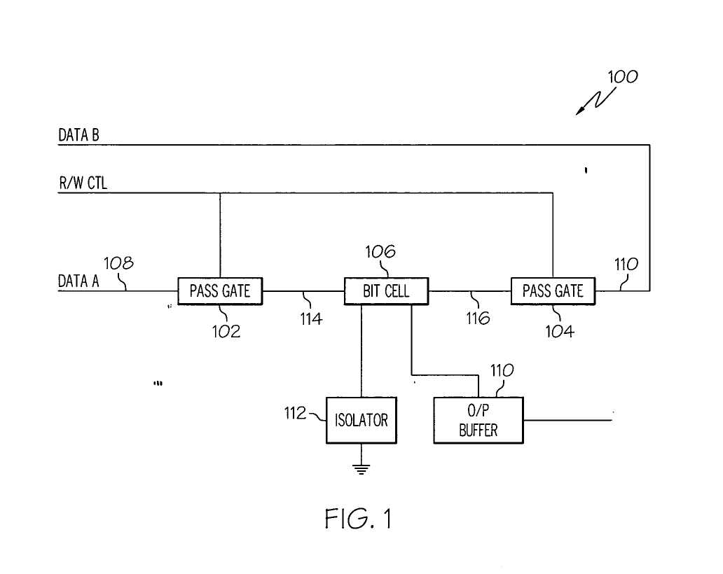

Referring to FIG. 1, a memory system 100 is illustrated. The system 100 can include pass gate 102, bit cell 106, pass gate 104, return rail isolator or just isolator circuit 112, and output buffer 110. The bit cell 106 may include two cross-coupled invertors (not shown). A differential signal (DATA and DATA B) can be applied to bit cell 106 via pass gates 102 and 104. The differential signal can set or reset the value stored by the bit cell 106 (i.e. a logic one or a logic zero). During the write operation, pass gate 102 can be turned on such that the DATA A signal is connected to one side of the bit cell 106 and pass gate 104 can be turned on such that DATA B is connected to the other side of the bit cell 106. Pass gates 102 and 104 can be manufactured as an N-channel field effect transistor (N-FET).

The differential signal as measured across DATA A and DATA B can provide a signal that represents either a logic high or a logic low. During a write operation, DATA A line 108 can be driven high or low by registers or line drivers within a processor (not shown) and DATA B line can be driven to the opposite logic value. When the pass gates 102 and 104 are “turned on” the differential signal can be applied to the input gates of transistors of the bit cell 106 until the bit cell 106 “flips” to the appropriate state. Accordingly, the bit cell 106 can store the appropriate value during this write cycle.

Using a differential signal to set or reset the bit cell 106 can provide added reliability for a write process, however, using a differential signal to drive the bit cell 106 generally, consumes more power than a single ended signal. Either single ended or differential signaling can be utilized by the system 100 without parting from the scope herein. At low supply voltages, such as supply voltages lower than one volt, a memory circuit such as memory circuit 100 can be sensitive to switching threshold values. In addition, currents and voltages that supply the nodes of the bit cell 106 can “fight” each other prior to a transition of state slowing the transition of state of the bit cell 106. Thus, when node voltages rise slowly or do not reach sufficient levels the bit cell 106 may not switch states possibly causing switching delays and/or write failures. Isolator circuit 112 can decouple the bit cell 106 from a supply return connection/node or ground plane and during such transitions isolating the bit cell from ground can reduce the contention between the competing voltages and currents.

In traditional memory cell configurations that utilize higher operating voltages, (over one volt) a write signal and a data signal is applied and such control functions are typically sufficient to achieve a successful write. Reducing the current flow to ground or isolating the bit cell during a write process via the isolator 112 can improve write performance at lower operating voltages. Accordingly, the bit cell storage voltage and/or data retention voltage of the bit cell 106 can be improved by disabling the isolation circuit 112 (reconnecting the bit cell to ground) before, or just as the pass gate control signal and the data signal is de-asserted at the end of the write cycle.

During a read cycle, the isolator 112 can remain off and the system 100 can operate substantially similar to traditional systems. During a write cycle, where the bit cell 106 is written to, but does not change state (because the data line and the bit cell are at the same logical state) the isolator circuit 112 can be sent a control signal to isolate the bit cell 106 and this configuration can provide a pre-charged feature similar to traditional pre-charge features.

Generally, toggling the bit cell 106 to a different state requires the DATA and DATA B lines to drive the input nodes 116 and 118 to a sufficient voltage level to switch the transistors in the bit cell 106. As stated above, switching transistors in the bit cell 106 can content or compete to raise voltages to switching levels while power supply rails and devices supply and/or sink currents. This competition can delay and possibly prevent the switching of the bit cell 106 to a different state. This contention can be even more pronounced at lower supply voltages (Vcc) as the threshold voltage (Vt) of the transistors can have variations.

It can be appreciated that a transistors threshold voltage does not change a significant amount in relationship to the supply voltage. Generally, threshold voltage is a function of how the device is manufactured. Device variations such as device channel lengths and threshold voltages (Le and Vt) exacerbate the switching thresholds of a memory circuit when the circuit is operated at lower supply voltages. Thus, at low voltages, the bit cell 106 may become more susceptible to write failures because the bit cell 106 will not toggle or switch states during a write process. The majority of such failures occur when the processor core cannot provide a high enough output voltage, quickly enough to reliably flip the polarity of the input node(s) 116 and 118 of the bit cell 106.

In addition, as a result of device variations, many conventional bit cell structures have conflicting sizing requirement between P-channel field effect transistors (P-FETs) of the invertors in the bit cell 160 and N-channel FET (NFETs) that create the pass gates. For example, in order to achieve a lower retention voltage, PFETs are often upsized which, in turn, degrades switching performance or write performance leading to write failures in such designs.

Isolator circuit 112 can be connected to the NFETs of the cross coupled inverters in the bit cell 106 and can isolate the NFETs from ground during the transition period/write cycle, interrupting the current to the ground rail and allowing the NFETS to “float” during part of the transition/switching process. The voltage across the isolator 112 can increase providing a small voltage drop between the bit cell 106 and ground during a transition of the bit cell 106 to different states. The isolator 112 can be controlled by a write interrupt signal or a “wr/int” signal.

Isolation of the bit cell 106 during transition can improve the conflicting requirements between retention of a signal in the bit cell 106, and writability to the bit cell 106. By assisting in the bit cell transition, the isolator 112 can allow the bit cell 106 to reliably operate at a much lower voltage than traditional cells even when significant device variations exist throughout the system 100.

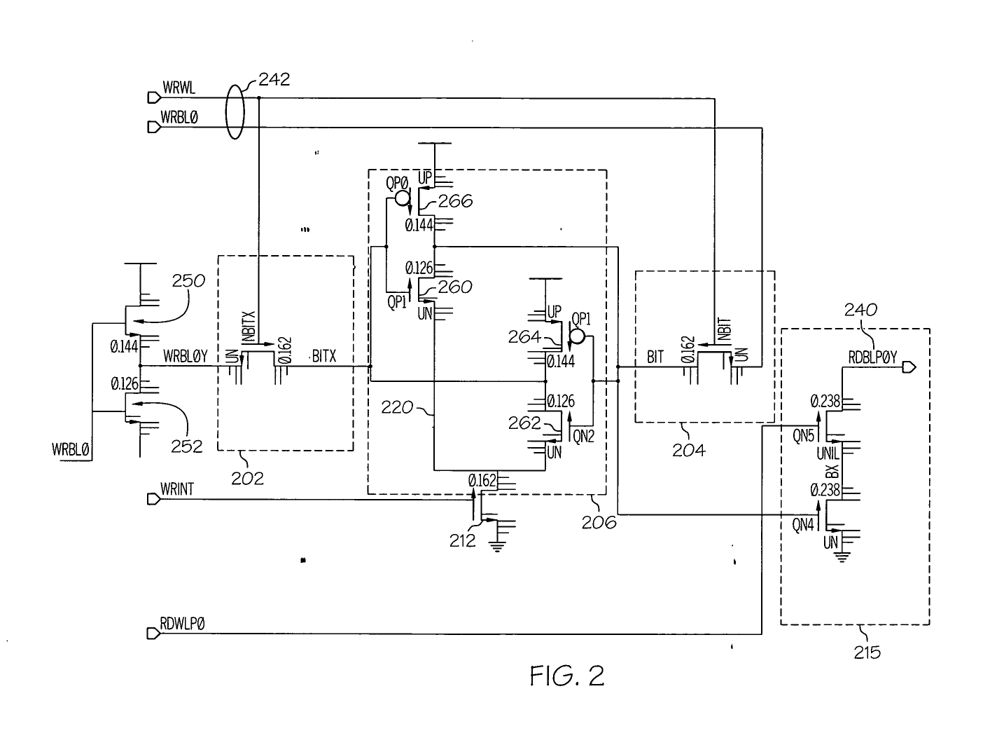

Referring to FIG. 2, a memory system 200 is illustrated. The memory system 200 can include pass gate 202, bit cell 206, pass gate 204, isolator circuit 212, and output buffer 240. The bit cell 206 may include two cross-coupled invertors formed by transistors 260, 262, 264 and 266 (transistors 260-266). A differential signal (DATA A and DATA B) can be applied to bit cell 206 via pass gates 202 and 204 and the differential signal can set or reset the value stored by the bit cell 206. During the write operation, pass gate 202 can be turned “on” such that the DATA A signal is connected to the bit cell 206 and pass gate 204 can be turned “on” such that DATA B is connected to the bit cell 206.

Isolator circuit 212 can be a switching device such as one or more transistors. Isolator circuit 212 can be connected between the bit cell 206 and a power return or a ground. In some embodiments, isolator circuit 212 can be manufactured using an N-channel metallic oxide semiconductor device or N-channel field effect transistor. Isolator 212 can decouple transistors 260-266 from ground during specific portions of the write cycle. When transistor 260 turns on, then the voltage on the drain of transistor 262 can increase making it easier for the cell 206 to change states. Likewise, if transistor 262 turns on, then the voltage on the drain of transistor 260 can increase making it easier for the cell 206 to change states.

Although the isolator circuit 212 is illustrated in close proximity to the bit cell 206, in some embodiments placement of the isolator circuit 212 can be a relatively long distance away from the cell 106. For example, the isolator circuit 212 can be located several nanometers or even tens of nano-meters away from the bit cell 206. In some embodiments isolators may located in arrays a relatively long distance from the bit cell 206.

As stated above isolator circuit 212, can be a switching device that can be controlled by a control signal referred to as a “wr/int” signal. In some embodiments the wr/int signal can be an inverted version of the signal provided on a write word line “wr/wl” signal. In other embodiments the wr/int signal can be synchronized with the signal found on the write word line with a specific time off set. For example, the wr/int line may change states just prior the write word line changing states. In some embodiments, when the write word line is at a logic high, the wr/int can be at a logic low and when the wr/wl is at a logic low the wr/int can be at a logic high. Thus, the switch within isolator 212 can be turned off during a write cycle to isolate the bit cell 206 from ground. In some embodiments, during a write operation, a logic high on the write word line signal or wr/wl for a particular row of bit cells can be asserted and concurrently, the wr/int signal be de-asserted to isolate the bit cell from ground during these transitions. Allowing the voltage on node 220 to rise during the transition, allows the disclosed configuration to operate at low voltages even when the system 200 has significant device variations.

Device variation in the system 200 can cause different threshold voltages (Vt) and different device channel lengths (Le) of transistors 260-266. The isolation circuit 112 can reduce the affects or device variations on cell performance (the ability to switch and to switch fast) as compared to traditional designs. Such variations can make the cross coupled inverters formed by transistors 260-266 stronger relative to the writing device such as NMOS devices 250 and 252. The NMOS devices of the bit cell 206 can also be interrupted so they can “float” when the wr/int signal isolates the cell 206 from ground, where this isolation allows the switching sensitivity due to device variations to be reduced.

The memory system 200 can include one write port 242 and one read port 240. As stated above, the storage portion of the system cell can be a six transistor configuration having a “dual ended” structure that is controlled by the write word line (wr/wl) that turns on the pass gates 202 and 204. The data input to the write port 242 can be a dual rail signal indicated by “wrbl0y” and “wrbl0” where a differential signal can be utilized to provide opposite polarities on these lines. Two transistors can form a read port 215 having an output signal read bit line address “rd/bl/p0y.” The read port 215 can provide a signal when activated by the read word line “rd/wl/p0.”

As a voltage is applied to the input nodes of the bit cell 206, it can be appreciated that it takes a finite amount of time for the voltage on the input nodes of the bit cell 206 to rise to a level that will trip the state of the cell. A write completion voltage level can be defined as a percentage of the supply voltage that is present on the write lines at the completion of write cycle. Generally, the higher the write completion voltage the better the performance of the cell. The completion of the write cycle can occur when the NMOS devices 202 and 204 are turned off by the wl/wl signal. The write completion voltage level can be utilized as a performance metric where a higher write completion level can be an important metric of cell performance particularly when the cell 206 is being utilized as high performance memory. In some embodiments a write completion voltage of less than sixty percent of a supply voltage can still change the state of the bit cell when isolator circuit 212 is utilized.

When a processor utilizes a register file to store data, the read cycle can occur in the phase or clock cycle immediately after the write of the bit to the cell 206. The use of isolator circuit 212 allows the write completion voltage to become relatively close to Vcc by allowing the NMOS devices 260 and 262 that are resisting or contending the write voltage to float as the bottom node of the bit cell is isolated from ground. Accordingly, the higher write completion voltage created by the isolator circuit can result in a higher overdrive voltage (the voltage that drives for the bottom NMOS of the read port) and with such a higher voltage can ensure that the NMOS transistors in the bit cell switch to the appropriate state by the end of write cycle.

Another bit cell metric can be an “output_low_to_high” trip point of the inverters within the bit cell 206. In some embodiments, the system 100 can also provide an improved, “output low to high” trip point of the inverters within the bit cell 206. When devices 250 and 252 are driving a logic high to the lit cell 206, the P-channel metallic oxide semiconductor (PMOS) devices (transistors 260 and 264) can complete the write of the logic high as they toggle or change state and switch on. “Disabling” the N-channel metallic oxide semiconductor (NMOS) pull down transistors 260 and 262 in the cell 206 during this transition via the isolator 212 enables the PMOS pull up devices 244 and 266 to switch faster such that the write of a logic one can be accomplished substantially faster.

A less than ideal voltage applied to the inputs of devices 260-266 that transition during a write operation can result in either, the PMOS devices 264 and 266 not being able to trip the inverter, or the PMOS devices 264 and 266 taking a very long time to transition, resulting in much slower operating speeds at low supply voltages. The isolator 212 can significantly reduce the trip point of the cell 206 thus, a lower write voltage can successfully write data to the cell. Reducing the trip points can solve switching problems by isolating interrupting the cross coupled inverter NMOS pull down transistors 260 and 262 allowing the PMOS devices 264 and 266 to pull up the node with less contention between the devices (266 and 260) and (264 and 262).

The system 200 can work equally well with multi-write-port memory systems. For a multiport configuration, a cross coupled inverter with NMOS pull down transistors 260 and 262 can be driven by an NMOS device that provides a write interrupt control signal that is derived from an OR gate coupled to numerous write control lines.

It can be appreciated that a single interrupt control signal can be provided to numerous isolator circuits 212. To further reduce overhead, a single isolator circuit 212 could be utilized to isolate numerous bit cells. Accordingly, as the number of bit cells increases, the overhead required to provide the write interrupt feature to bit cells can become a smaller percentage of the overall system.

It can also be appreciated that at higher voltages, (i.e. voltages greater than ˜1.1 volt) the disclosed bit cell configuration can switch states seven percent (7%) faster than a bit cell configuration without an isolator circuit. This determination has been made under the condition that the transistors that comprise the system (212, 250, 252, 260-266) are “nominal” devices (i.e. no variations or zero sigma). It has been determined that with nominal devices operated at lower voltages, such as say ˜0.775 volts, the addition of the isolator circuit provides a “logic high” write completion delay performance that is three percent (3%) faster than traditional designs.

The term “six sigma” as utilized herein refers to the ability of a highly capable semiconductor manufacturing process to produce a product with a specific default level. In particular, processes that operate with six sigma quality can produce a semiconductor with defect levels below three point four (3.4) defects per million opportunities (3.4 DPMO). Six sigma's implicit goal is to improve all processes to a 3.4 DPMO level of quality or better. Accordingly, using a six sigma reliability target, which is close to a typical target sigma for a CPU design, the isolator circuit 212 can improve switching speed by twenty percent (20%) when compared to traditional cell designs indicating that the isolator circuit 212 can make a memory system much more tolerant of device variations. At lower voltages, and at a six sigma target, the isolator circuit 212 can allow the bit 206 cell to switch two and seven tenths (2.7) times faster than traditional bit cell designs.

Memory systems without an isolator circuit can approach an infinite switching delay, near the six sigma target, at operating voltages below one volt. This indicates that bit cells without an isolator circuit are at or near their low voltage operating limit for six sigma performance at a supply voltage of one volt. In contrast, the isolator circuit 212 feature can allow a memory system to meet the six sigma criteria when powered by less than one volt. Thus, the isolator circuit feature can provide a much better manufacturing yield particularly when the bit cell 206 will be operated with lower supply voltages.

It can be appreciate that the isolator circuit feature allows a memory system to achieve a higher write completion voltage and thus a faster transition time when the cell transitions from a logic low to logic high. The isolator circuit feature can reduce the contention between the inverters of the bit cell or between the opposite sides of the cross coupled inverters. Generally, this contention (supply currents and bias voltages) that slows the switching of the cell can be reduced or eliminated earlier in the write cycle when an isolator circuit is utilized, resulting in reduced write delay. In addition to the zero sigma delay improvement over traditional systems mentioned above, the isolator circuit can provide improved results at higher sigmas for a logic low write completion voltage, indicating that the isolator circuit 212 can significantly increase variation tolerance of a memory system at all voltages.

Intrinsic device variations often show Le variations proportional to one divided by the square root of the device width, and Vt variation proportional to one divided by the square root of the area under the gate of the device. It is anticipated that intrinsic device variations will increase in future manufacturing technologies as device width and length continue to be reduced by newer technologies. Thus, the isolator feature may improve memory yield and functionality in future generations of circuits having smaller devices.

Intrinsic device variations often show Le variations proportional to one divided by the square route of the device width and Vt variation proportional to one divided by the square route of the area under the gate of the device. Therefore, it is anticipated that intrinsic device variations will increase in future manufacturing technologies as device width and length continue to be reduced.

During manufacturing the size ratio of P-channel to N-channel transistors in a memory cell can vary and this can affect the low voltage yield of the system. This ratio sensitivity can make it difficult to predict memory performance at low supply voltages. This is particularly true for pinch off voltage modeling for circuits under development. Many integrated circuit vendors are placing an increased emphasis on ultra low voltage operation utilizing additional cores. These additional cores can be designed for a fixed thermal design power (TDP) and with a smaller form factor to name a few. Thus, it is a design goal of many to have more cores on future chips with smaller Z and Le and thus, future memory designs that are more variation tolerant may be desired.

Intrinsic device variations often show Le variations proportional to one divided by the square route of the device width and Vt variation proportional to one divided by the square route of the area under the gate of the device. Smaller devices inherently have higher manufacturing variations. Accordingly, it is anticipated that intrinsic device variations will increase in future manufacturing technologies as device width and length continue to be reduced.

It can be appreciated that in some production runs over three percent of the integrated circuits must be discarded or scrapped (currently a 97% yield is achievable) due to variation sensitivity where high performance processor memory does not pass low voltage testing. When smaller devices are utilized, variation sensitive circuits will be most likely become more prevalent and the manufacturing yield will significantly decrease. The isolator circuit can counter the increase in variations will likely result in future technologies.

Many design tools can simulate memory circuit operation. One parameter often simulated is the relative drive current strength ratio of PMOS devices to NMOS devices. This ratio can change from the expected value due to manufacturing variations. For example, if the PMOS devices are relatively stronger that the NMOS devices, (and this is not detected by design and simulation tools) then, the processor may not function at low voltages since the NMOS devices have a harder time overcoming the influence of the PMOS keeper devices. Some technologies utilize a jam circuit to overcome the contention of a keeper circuit to in order to successfully complete the desired operation. Jam circuits can be sensitive to PMOS vs. NMOS strength ratio fluctuations. The P-channel and N-channel drive current ratio range can modulate with temperature because P-channel versus, N-channel mobility can change with temperature. This temperature sensitivity can make it difficult to predict performance of the bit cell at low supply voltages particularly for pinch off voltage modeling. Thus as P-channel vs. N-channel variations increase in future technologies a more variation tolerant circuit becomes very useful.

Many integrated circuit vendors are placing an increased emphasis on ultra low voltage operation utilizing additional cores. These additional cores can be designed for a fixed thermal design power (TDP) and with a smaller form factor to name a few. It is possibly a design goal of many to have more cores on future chips with smaller Z and Le and this may drive a requirement that future memory designs are more variation tolerant.

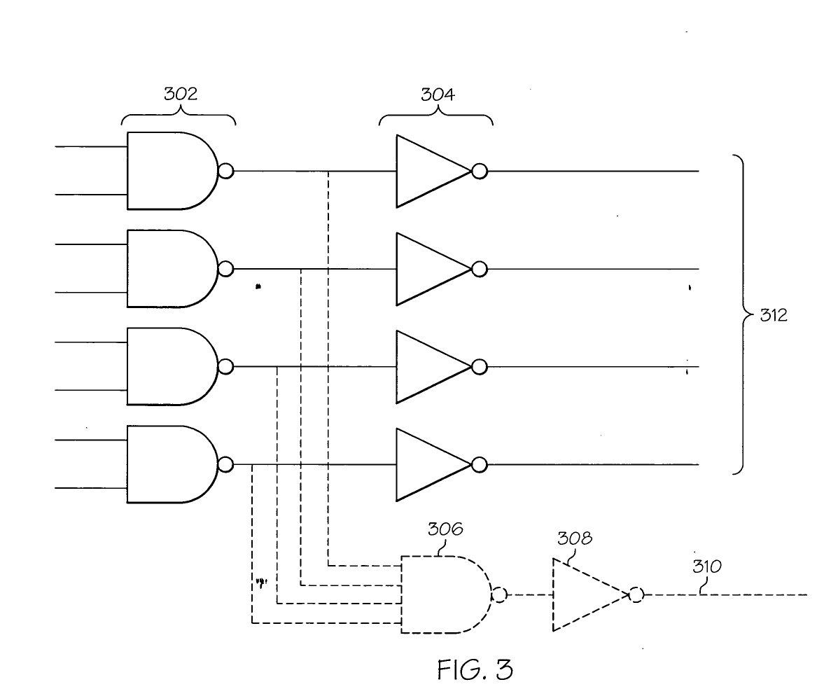

Referring to FIG. 3, a control signal generator 300 that can generate a write interrupt control signal (wr/int) is illustrated. The wr/int signal provided on line 310 can be the wr/int signal referred to in FIG. 2. The signal generator 300 can receive write control signals from multiple write ports, where only four write inputs are illustrated in FIG. 3. The signal generator 300 can include NAND gates 302, inverters 304, multiport NAND gate and inverter 308. The generator 300 can provide a write control signal to memory cells or bit cells (not shown) via lines 312. In some embodiments, the generator can provide a write control signal to columns or rows of memory cells (not shown).

The wr/int signal on line 310 can be clocked with a main system clock of the integrated circuit such that the wr/int signal can be synchronized with a write control line. In some embodiments, the four write lines 314 can be connected to four different bit cells or the four write lines 314 can be connected to four different banks of memory cells. Thus the four write lines can be controlled from different clocks. The wr/int signal on line 310 can be derived by “anding” the clock signals with write control signals and inverting the output signal utilizing NAND gates 302.

In some embodiments, the write interrupt signal (wr/int) on line 310 may remain at a logic low during write cycles, however, at other times the interrupt signal can transition to a logic high and remain in a logic high state without affecting bit cell operation. Further, it can be appreciated that the NAND gates 302 and inverters 304 illustrated are generally existing in a memory system, thus, in some embodiments the additional overhead required to create the wr/int signal is a multi-input NAND gate and an inverter (306 and 3081.

Accordingly, to create a wr/int signal that will be controlled by four write lines, a multi-input NAND gate 306 and an inverter 308 can be coupled to existing components of a memory control circuit. It can be appreciated that the output 310 can provide an interrupt signal to many isolator circuits or many bit cells, possibly limited by the fan-out or drive properties of the output of the inverter 308.

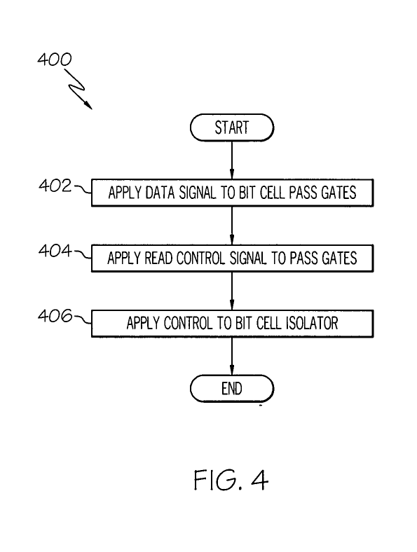

Referring to FIG. 4 a flow diagram 400 for operating a bit cell is disclosed. It can be appreciated that operating the disclosed memory circuit does not require a sequential “cycle” or need to proceed in a “step wise” fashion as a flow diagram may appear or may imply. Accordingly, many of the signals and output can occur simultaneously. Further, the operation of the memory system can be described in terms of signal levels that are required to achieve a write to or a read from the bit cell and this may be explained as a “sequential” or non-sequential operation. Thus, it can be appreciated that, the order of applying the data signal, pass gate control and bit line isolation signal does not need to occur in the sequence provided by the flow diagram 400.

At higher operating voltage, a write to a bit to a bit cell can be achieved by applying a data signal and a pass gate control signal to the bit cell without utilizing the bit cell write interrupt/isolation feature. Applying the bit cell isolation (simultaneously with the pass gate and data signals), however, allows the write process to function reliably at lower operating voltages. Bit cell voltage/data retention can be improved by disabling the bit cell isolation before or just as the pass gate control/data is de-asserted. A read function can be reliably conducted by not isolating the bit cell while applying the pass gate control with benign data values (typically pre-charged to high voltage to the pass gates data inputs).

As illustrated by block 402, a data signal can be provided to a pass gate or pass gates of a bit cell. As illustrated by block 404, a read or a write control signal can be applied to the pass gate. As illustrated by block 406, during a write cycle or phase a write isolation control signal can be applied to an isolator/interrupter circuit. The isolator circuit can be controlled by the isolator signal that may se an inverted version of the write signal. In some embodiments, the interrupt signal (wr/int) can have transitions' that lead or lag the write control signal and in some embodiments the wr/int signal can have a shorter duty cycle or be a shorted inverted version of the write control signal. After the write process is completed, the process can end.

Although the isolation mode bit cell and some of its advantages have been described in detail for some embodiments, it should be understood that various changes, substitutions and alterations may be made herein without departing from the spirit and scope of the invention as defined by the appended claims. Although an embodiment of the invention may achieve multiple objectives, not every embodiment falling within the scope of the attached claims will achieve every objective. Moreover, the scope of this document is not intended to be limited to the particular embodiments of the process, machine, manufacture, composition of matter, and methods described in the specification.

As one of ordinary skill in the art will readily appreciate from the teachings herein processes, machines, manufacture, compositions of matter, or methods presently existing or later to be developed that perform substantially the same function or achieve substantially the same result as the corresponding embodiments described herein may be utilized according to some embodiments of the invention. Accordingly, the appended claims are intended to include within their scope such processes, machines, manufacture, compositions of matter or methods.

What is claimed is:

1. An apparatus comprising:
a bit cell,
a first pass gate coupled to the bit cell to receive a write signal during a write cycle;
a second pass gate coupled to the bit cell to receive the write signal during the write cycle; and
a bit cell isolator circuit to isolate at least a portion of the bit cell from a power return during at least a portion of the write cycle.

2. The apparatus of claim 1, further comprising a write interrupt control circuit coupled to the bit cell isolator circuit to generate a write interrupt signal.

3. The apparatus of claim 2, wherein the write interrupt control circuit comprises at least one of an AND gate, a NAND gate and an inverter.

4. The apparatus of claim 2, wherein the write interrupt control circuit is coupled to a plurality of write control lines.

5. The apparatus of claim 1, wherein the bit cell comprises sub-65 nano-meter N-channel field effect transistors.

6. The apparatus of claim 1, further comprising a write port coupled to the bit cell.

7. The apparatus of claim 1, further comprising a first and second N-channel field effect transistor to drive an input node of the bit cell.

8. The apparatus of claim 1, wherein the bit cell comprises N-channel field effect transistors and P-channel field effect transistors and wherein the bit cell isolator is coupled to the N-channel field effect transistors.

9. The apparatus of claim 1, wherein the bit cell isolator circuit to decouple the bit cell from ground before the write signal is de-asserted.

10. The apparatus of claim 1, wherein the bit cell isolator circuit to decouple the bit cell from ground during write signal de-assertion.

11. A method comprising:
applying a control signal to a first pass gate during a write phase;
applying a data signal to a bit cell via the first pass gate during the write phase; and
applying an isolation control signal to a bit cell isolator during at least a portion of the write phase to isolate at least one component within the bit cell from a return node during the write phase.

12. The method of claim 11, further comprising applying a control signal to a second pass gate during the write phase.

13. The method of claim 11, further comprising creating the isolation control signal from a plurality of write control signals.

14. The method of claim 11, further comprising inverting a write signal and controlling the bit cell isolator with the inverted write signal.

15. The method of claim 11, further comprising providing the isolation control signal to the bit isolator before the control signal is de-asserted.
